(19) United States
(12) Patent Application Publication
(10) Pub. No.: US 2006/0154428 A1
(43) Pub. Date: Jul. 13, 2006

(54) INCREASING DOPING OF WELL COMPENSATING DOPANT REGION ACCORDING TO INCREASING GATE LENGTH

(75) Inventor: Omer H. Dokumaci, Wappingers Falls, NY (US)

Correspondence Address: HOFFMAN, WARNICK & D'ALESSANDRO LLC, 75 STATE ST, 14TH FL, ALBANY, NY, 12207, US

(73) Assignee: INTERNATIONAL BUSINESS MACHINES CORPORATION, ARMONK, NY (US)

(21) Appl. No.: 10/905,591

(22) Filed: Jan. 12, 2005

(51) Int. Cl. H01L 29/76; H01L 21/336

(52) U.S. Cl. 438/302; 257/288

(57) ABSTRACT

Methods and resulting structure of implementing a compensating implant that creates more compensation doping as the gate length is increased are disclosed. In particular, the invention performs an angled compensation implant through a gate opening during the damascene process such that the compensating dopant concentration increases as the gate length increases. In this fashion, the threshold voltage of a longer device is reduced much more than the threshold voltage of a shorter device, thereby reducing the threshold voltage of the longer device to acceptable levels without affecting the threshold voltage of the shorter device. The invention is especially advantageous relative to super-steep retrograde wells.

### BACKGROUND OF THE INVENTION

1. Technical Field

The present invention relates generally to semiconductor device fabrication, and more particularly, to methods and resulting semiconductor device structure of implementing a channel compensating dopant region that creates more compensation doping as the gate length increases.

2. Related Art

Reduction of threshold voltage is a continuing concern in semiconductor device structures. One particular structure in which threshold voltages are considered too high for long gate devices are super-steep retrograde well (SSRW) transistor devices. The term “retrograde well” indicates that the well is formed using an approach in which the highest concentration of dopant (implanted) in the well is located at a certain distance from the surface, which makes the device less susceptible to punch-through. The term “super-steep” indicates that the transition from the lower concentration of dopant to the higher concentration is fairly abrupt, i.e., a dopant profile has a super-steep attribute at the transition.

FIGS. 1 and 2 show graphical representations of rolloff characteristics of threshold voltages (Vtsat) versus gate length (Lpoly) for nFETs with a Vdd of 0.8V. FIG. 1 shows graphs for a silicon thickness of 480 Å, and for devices having: no SSRW (circle), an SSRW having a 7.96e18/cm³ dopant concentration (square) and an SSRW having a 2.72e19/cm³ dopant concentration (diamond). FIG. 2 shows graphs for a silicon thickness of 120 Å, and for devices having: no SSRW (circle), an SSRW having a 1.5e19/cm³ dopant concentration (square) and an SSRW having a 5e18/cm³ dopant concentration (diamond). As illustrated, as gate length increases, the threshold voltages increase to unacceptable levels for those devices employing an SSRW. The problem is magnified as the silicon becomes thinner, as illustrated by FIG. 2. The range of threshold voltages for SSRW devices based on gate length presents a challenge to fabricating devices having different sizes.

In view of the foregoing, there is a need in the art to reduce the threshold voltage for devices employing an SSRW depending on gate length.

### SUMMARY OF THE INVENTION

The invention includes methods and resulting structure of implementing a compensating implant that creates more compensation doping as the gate length is increased. In particular, the invention performs an angled compensation implant through a gate opening during the damascene process such that the compensating dopant concentration increases as the gate length increases. In this fashion, the threshold voltage of a longer device is reduced much more than the threshold voltage of a shorter device, thereby reducing the threshold voltage of the longer device to acceptable levels without affecting the threshold voltage of the shorter device. The invention is especially advantageous relative to super-steep retrograde wells.

A first aspect of the invention is directed to a method of implementing a compensating dopant region, the method comprising the steps of: providing a gate electrode including a spacer surrounding a gate material area and a gate dielectric, the gate electrode being positioned over a well in a substrate; forming a planar dielectric layer about the gate electrode; removing the gate material area and the gate dielectric from the gate electrode to form a gate opening; performing an angled implant into the gate opening to form the compensating dopant region in the well; and annealing to activate the compensating dopant region.

A second aspect of the invention includes a semiconductor device structure comprising: a gate electrode including a spacer surrounding a gate material area and a gate dielectric; a super-steep retrograde well positioned under the gate electrode in a substrate; and a compensating dopant region positioned with the super-steep retrograde well, wherein an amount of dopant in the compensating dopant region is based on a length of the gate material area.

A third aspect of the invention includes a method of forming a gate electrode including a compensating dopant region, the method comprising the steps of: providing a gate electrode including a spacer surrounding a gate material area and a gate dielectric, the gate electrode being positioned over a super-steep retrograde well in a substrate; forming a planar dielectric layer about the gate electrode; removing the gate material area and the gate dielectric from the gate electrode to form a gate opening; performing an angled implant into the gate opening to form the compensating dopant region in the super-steep retrograde well such that an amount of dopant implanted increases with a length of the gate opening; annealing to activate the compensating dopant region; and re-forming the gate dielectric and the gate material area in the gate opening.

The foregoing and other features of the invention will be apparent from the following more particular description of embodiments of the invention.

### BRIEF DESCRIPTION OF THE DRAWINGS

The embodiments of this invention will be described in detail, with reference to the following figures, wherein like designations denote like elements, and wherein:

FIG. 1 shows a graphical representation of rolloff characteristics of threshold voltages versus gate length for a set of devices having a first silicon thickness.

FIG. 2 shows a graphical representation of rolloff characteristics of threshold voltages versus gate length for a set of devices having a second silicon thickness.

FIGS. 3-7 show a method of implementing a compensating dopant region according to the invention.

FIG. 8 shows a final step of the method of FIGS. 3-7 and a semiconductor device structure formed.

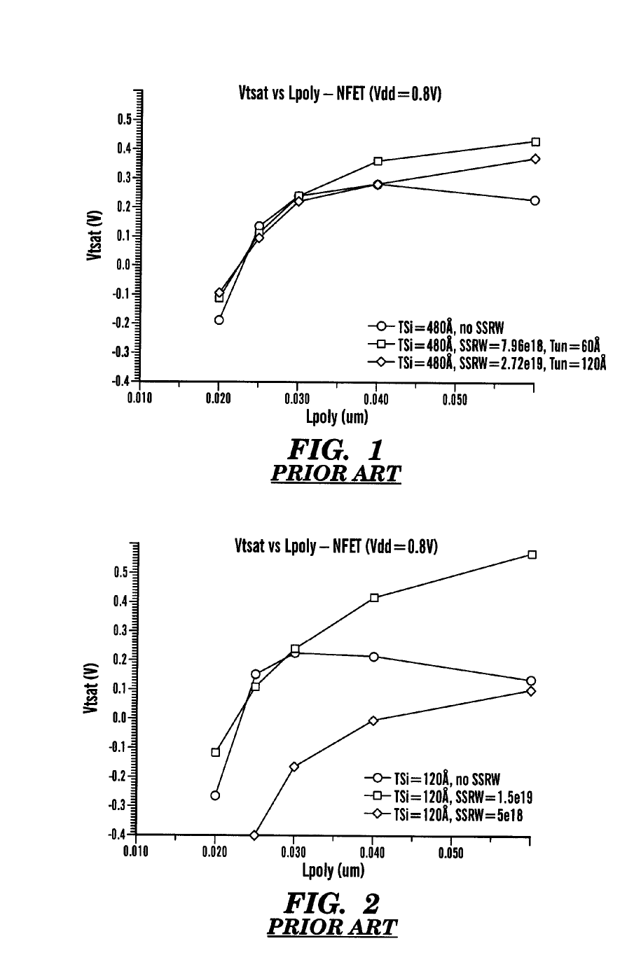

### DETAILED DESCRIPTION OF THE INVENTION

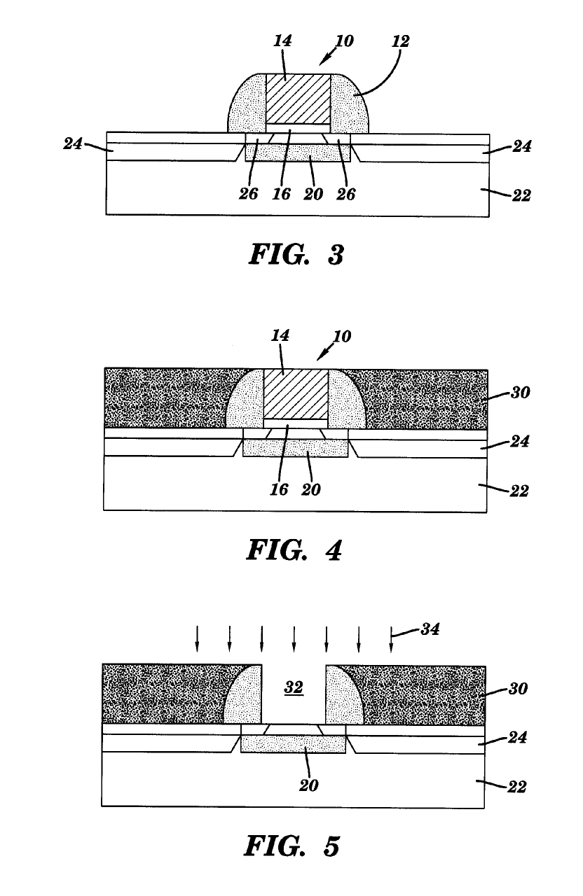

With reference to the accompanying drawings, FIG. 3 illustrates initial structure for a method of implementing a compensating dopant region according to the invention. As shown, a gate electrode 10 is provided including a spacer 12 surrounding a gate material area 14 and a gate dielectric 16. Gate electrode 10 is positioned over a well 20 in a substrate 22. Also shown are source-drain regions 24, and base extensions 26. In one embodiment, well 20 includes a super-steep retrograde well, as defined above. The type and amount of dopant in well 20 will vary depending on the type of device desired. For example, for an nFET, dopant would be p-type in well 20. In one embodiment, a super-steep retrograde well 20 has a dopant concentration greater than 5.0e18/cm³, although this is not necessary.

As shown in FIG. 4, a next step includes forming a planar dielectric layer 30 about gate electrode 10. Planar dielectric layer 30 may be formed by deposition of, for example, silicon dioxide (SiO₂) (preferred) or silicon nitride (Si₃N₄) in any conventional fashion, and chemical mechanical polishing (CMP) to planarize.

FIG. 5 shows a next step in which gate material area 14 and gate dielectric 16 (FIGS. 3 and 4) are removed from gate electrode 10 to form a gate opening 32. In one embodiment, gate material area 14 and gate dielectric 16 are removed by performing a conventional isotropic etch 34.

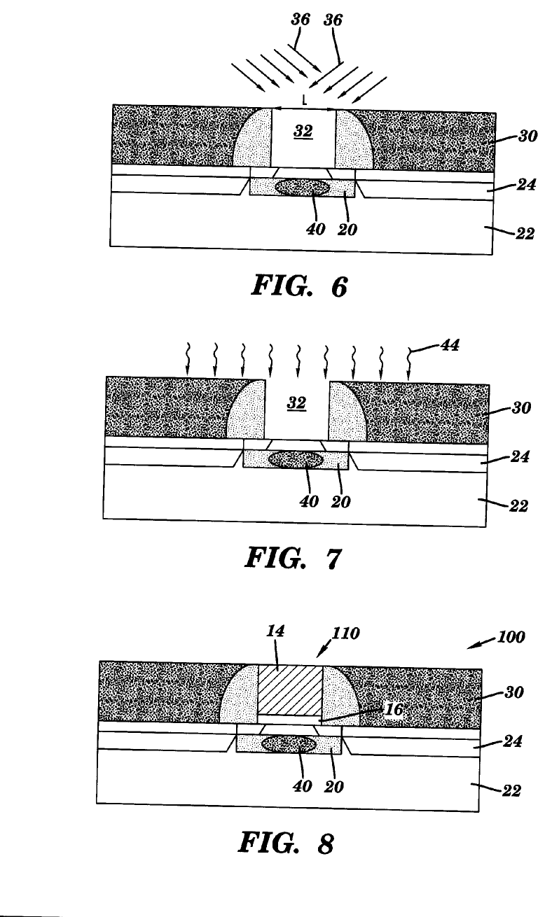

FIG. 6 shows a next step in which an angled implant 36 is performed into gate opening 32 to form a compensating dopant region 40 in well 20. Angled implant 36 can be performed in any conventional fashion, e.g., angling of substrate 22 on a plate of an acceleration type ion implanter. The material implanted can vary depending on the desired type device, e.g., for an nFET, dopant would be n-type to compensate for the p-type dopant of well 20. Observing FIG. 6, it can be determined that an amount of dopant implanted increases with a length (L) of gate opening 32. More specifically, partial masking of angled implant 36 by planar dielectric layer 30 determines the amount of implantation within gate opening 32. For smaller gate opening 32 lengths, angled implant 36 will create less doping in well 20 (i.e., channel region) than would be created for longer gate opening 32 lengths. Consequently, the amount of reduction of a threshold voltage (Vtsat) created by compensating dopant region 40 increases with a length of gate opening 32. In one embodiment, compensation dopant region 40 has a dopant concentration between 1.0e18/cm³ and 1.0e19/cm³.

FIG. 7 illustrates the next step of annealing 44 to activate compensating dopant region 40. In one embodiment, the annealing includes exposing gate opening 32 to a laser or performing a flash anneal to minimize diffusion.

Finally, as shown in FIG. 8, gate dielectric 16 and gate material area 14 are re-formed using conventional techniques to form semiconductor device structure 100 including a gate electrode 110 including a compensating dopant region 40. Subsequent processing may include any now known or later developed middle-of-line or back-end-of-line processing. Gate material area 14 may include any now known or later developed gate material such as doped polysilicon, metal or metal silicide. Gate dielectric 16 may include silicon dioxide dioxide (SiO₂), oxynitride (ON), silicon nitride (Si₃N₄) and/or a high dielectric constant material. An amount of dopant in compensating dopant region 40 of semiconductor device structure 100 is based on a length of gate material area 14, i.e., gate opening 32. Consequently, an amount of reduction of a threshold voltage (Vt) created by compensating dopant region 40 increases with a length of gate material area 14.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

1. A method of implementing a compensating dopant region, the method comprising the steps of:
providing a gate electrode including a spacer surrounding a gate material area and a gate dielectric, the gate electrode being positioned over a well in a substrate;
forming a planar dielectric layer about the gate electrode;
removing the gate material area and the gate dielectric from the gate electrode to form a gate opening;
performing an angled implant into the gate opening to form the compensating dopant region in the well, wherein the formed compensating dopant region provides compensation as a function of a length of the gate opening; and
annealing to activate the compensating dopant region.

2. The method of claim 1, wherein an amount of dopant implanted during the performing step increases with the length of the gate opening.

3. The method of claim 1, wherein an amount of reduction of a threshold voltage created by the compensating dopant region increases with the length of the gate opening.

4. The method of claim 1, wherein the planar dielectric layer includes one of: silicon dioxide (SiO₂) and silicon nitride (Si₃N₄).

5. The method of claim 1, wherein the removing step includes performing an isotropic etch.

6. The method of claim 1, wherein the annealing step includes one of exposing the gate opening to a laser and performing a flash anneal.

7. The method of claim 1, further comprising the step of re-forming the gate dielectric and the gate material area.

8. The method of claim 6, wherein the gate dielectric includes at least one of silicon dioxide (SiO₂), oxynitride (ON), silicon nitride (Si₃N₄) and a high dielectric constant material.

9. The method of claim 1, wherein the well includes a super-steep retrograde well.

10. A semiconductor device structure comprising:
a gate electrode including a spacer surrounding a gate material area and a gate dielectric;
a super-steep retrograde well positioned under the gate electrode in a substrate; and
a compensating dopant region positioned with the super-steep retrograde well, wherein an amount of dopant in the compensating dopant region is based on a length of the gate material area.

11. The semiconductor device structure of claim 10, wherein an amount of reduction of a threshold voltage created by the compensating dopant region increases with a length of the gate material area.

12. The semiconductor device structure of claim 10, wherein the super-steep retrograde well has a dopant concentration greater than 5.0e18/cm³.

13. The semiconductor device structure of claim 10, wherein the compensation dopant region has a dopant concentration of no less than 1.0e18/cm³ and no greater than 1.0e19/cm³.

14. The semiconductor device structure of claim 10, wherein the gate material area includes one of: doped polysilicon, metal and metal silicide.

15. The semiconductor device structure of claim 10, wherein the gate dielectric includes at least one of silicon dioxide (SiO₂), oxynitride (ON), silicon nitride (Si₃N₄) and a high dielectric constant material.

16. A method of forming a gate electrode including a compensating dopant region, the method comprising the steps of:
providing a gate electrode including a spacer surrounding a gate material area and a gate dielectric, the gate electrode being positioned over a super-steep retrograde well in a substrate;
forming a planar dielectric layer about the gate electrode;
removing the gate material area and the gate dielectric from the gate electrode to form a gate opening;
performing an angled implant into the gate opening to form the compensating dopant region in the super-steep retrograde well, wherein the formed compensating dopant region provides compensation as a function of a length of the gate opening, such that an amount of dopant implanted increases with the length of the gate opening;
annealing to activate the compensating dopant region; and
re-forming the gate dielectric and the gate material area in the gate opening.

17. The method of claim 16, wherein an amount of reduction of a threshold voltage created by the compensating dopant region increases with the length of the gate opening.

18. The method of claim 16, wherein the planar dielectric layer includes one of: silicon dioxide (SiO₂) and silicon nitride (Si₃N₄).

19. The method of claim 16, wherein the removing step includes performing an isotropic etch.

20. The method of claim 16, wherein the annealing step includes one of exposing the gate opening to a laser and performing a flash anneal.
